(19) United States
(12) Patent Application Publication
(10) Pub. No.: US 2024/0421138 A1
(43) Pub. Date: Dec. 19, 2024

(54) SEMICONDUCTOR PACKAGE AND METHOD FOR MAKING THE SAME

(71) Applicant: STATS ChipPAC Pte. Ltd., Singapore (SG)

(72) Inventors: JiSeon LEE, Incheon (KR); BumRyul MAENG, Incheon (KR); HyunKyu LEE, Incheon (KR)

(21) Appl. No.: 18/739,404

(22) Filed: Jun. 11, 2024

(30) Foreign Application Priority Data
Jun. 19, 2023 (CN) 202310733360.1

(51) Int. Cl. H01L 25/10; H01L 23/00; H01L 23/31; H01L 23/36; H01L 23/538; H01L 25/00

(52) U.S. Cl. CPC H01L 25/105; H01L 23/3107; H01L 23/36; H01L 23/5381; H01L 23/5386; H01L 25/50; H01L 24/16; H01L 2224/16225; H01L 2225/1094

(57) ABSTRACT

A semiconductor package and a method for making the same are provided. The semiconductor package includes: a substrate having a lower substrate surface and an upper substrate surface; a first interposer attached on the upper substrate surface; at least one first electronic component mounted on and electronically connected with the first interposer; a second interposer disposed above the at least one first electronic component, wherein the second interposer has a concave portion and a protruding portion, the at least one first electronic component is accommodated in the concave portion, and the protruding portion is mounted on the upper substrate surface; and at least one second electronic component mounted on and electronically connected with the second interposer.

### TECHNICAL FIELD

The present application generally relates to semiconductor technology, and more particularly, to a semiconductor package and a method for making the same.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Recently, SiP uses a Double Side Molding (DSM) technology to further shrink the overall package size. However, it is found that the package size is still increasing, and/or significant signal loss occurs.

Therefore, a need exists for further improvement to the structural arrangement of SiPs.

### SUMMARY OF THE INVENTION

An objective of the present application is to provide a semiconductor package with less signal loss and reduced package size.

According to an aspect of embodiments of the present application, a semiconductor package is provided. The semiconductor package may include: a substrate having a lower substrate surface and an upper substrate surface; a first interposer attached on the upper substrate surface; at least one first electronic component mounted on and electronically connected with the first interposer; a second interposer disposed above the at least one first electronic component, wherein the second interposer has a concave portion and a protruding portion, the at least one first electronic component is accommodated in the concave portion, and the protruding portion is mounted on the upper substrate surface; and at least one second electronic component mounted on and electronically connected with the second interposer.

According to another aspect of embodiments of the present application, a method for forming a semiconductor package is provided. The method may include: providing a substrate having a lower substrate surface and an upper substrate surface; attaching a first interposer on the upper substrate surface; mounting at least one first electronic component on the first interposer, the at least one first electronic component being electronically connected with the first interposer; mounting a second interposer above the at least one first electronic component, wherein the second interposer has a concave portion and a protruding portion, the at least one first electronic component is accommodated in the concave portion, and the protruding portion is mounted on the upper substrate surface; and mounting at least one second electronic component on the second interposer, the at least one second electronic component being electronically connected with the second interposer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a semiconductor package according to an embodiment of the present application.

FIG. 2 is a cross-sectional view illustrating a semiconductor package according to another embodiment of the present application.

FIG. 3 is a cross-sectional view illustrating a semiconductor package according to another embodiment of the present application.

FIG. 4 is a cross-sectional view illustrating a semiconductor package according to another embodiment of the present application.

FIGS. 5A to 5J are cross-sectional views illustrating various steps of a method for making a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

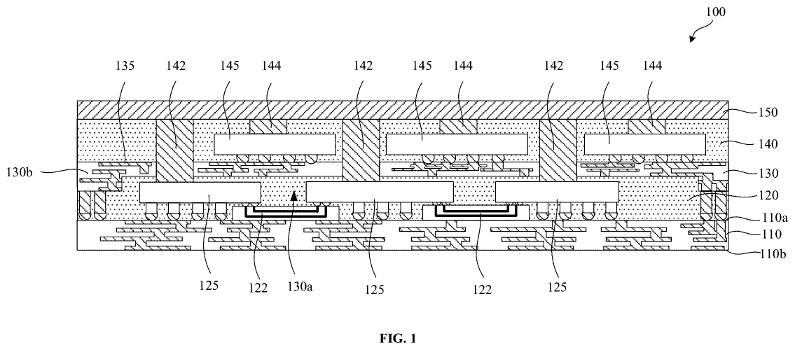

Referring to FIG. 1, a cross-sectional view of a semiconductor package 100 is illustrated according to an embodiment of the present application.

As shown in FIG. 1, the semiconductor package 100 may include a substrate 110 having an upper substrate surface 110a and a lower substrate surface 110b. At least one first interposer 122 is attached on the upper substrate surface 110a, and at least one first electronic component 125 is mounted on the first interposer 122 and is electronically connected with the first interposer 122. A second interposer 130 is disposed above the at least one first electronic component 125. The second interposer 130 may have a concave portion 130a and a protruding portion 130b, the at least one first electronic component 125 is accommodated in the concave portion 130a, and the protruding portion 130b is mounted on the upper substrate surface 110a. Further, at least one second electronic component 145 is mounted on the second interposer 130 and is electronically connected with the second interposer 130. As the first electronic component 125 is accommodated in the concave portion 130a, the overall size of the semiconductor package 100 can be reduced. Moreover, the first interposer 122 and the second interposer 130 can provide high connectivity for the electronic components mounted thereon, and thus the integration density and the performance of the semiconductor package 100 can be improved.

Specifically, the substrate 110 can provide support and connectivity for electronic components and devices. By way of example, the substrate 110 can include a printed circuit board (PCB), a carrier substrate, a semiconductor substrate with electrical interconnections, or a ceramic substrate. However, the substrate 110 is not to be limited to these examples. In other examples, the substrate 110 may include a laminate interposer, a strip interposer, a leadframe, or other suitable substrates.

In some embodiments, the substrate 110 may include a plurality of interconnection structures. The interconnection structures can provide connectivity for electronic components mounted on the substrate 110. The interconnection structures may define pads, traces and plugs through which electrical signals or voltages can be distributed horizontally and vertically across the substrate 110. For example, as shown in FIG. 1, the interconnection structures may include redistribution structures, and the redistribution structures can provide contact pads along the upper substrate surface 110a and/or the lower substrate surface 110b.

The first interposer 122 may be made of semiconductor material, glass, or organic materials with redistribution layers or wiring patterns formed therein. Preferably, the first interposer 122 is a silicon-based interposer (also known as a silicon bridge). The first interposer 122 may be fabricated using any suitable IC manufacturing processes and can offer various advantages. For example, the first interposer 122 can support fine pitches for through-silicon vias (TSVs) and traces used in signal and power distribution, and may have a thermal expansion coefficient which can match that of the semiconductor die or chiplet it is in contact with. For example, the first interposer 122 may include a semiconductor layer, a plurality of wiring patterns formed on the semiconductor layer, and a plurality of contact pads connected with the wiring patterns. The wiring patterns may include TSVs and traces with fine pitches. The contact pads can provide connectivity for electrical components mounted thereon.

Continuing referring to FIG. 1, at least one first electronic component 125 is mounted on the first interposer 122 and is electronically connected with the first interposer 122.

The at least one first electronic component 125 may include any of a variety of types of semiconductor dice, semiconductor packages, or discrete devices. For example, the at least one first electronic component 125 may include a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit (ASIC), etc. In some embodiments, the at least one first electronic component 125 may be small IC chips that contain different well-defined subsets of functionalities, and allow to integrate a variety of different architectures, different process nodes, and even dedicated silicon blocks or intellectual property (IP) blocks from different foundries into a single package. The at least one first electronic component 125 can be mounted on the first interposer 122 by flip-chip bonding or any other suitable surface mounting techniques.

In a specific example, the at least one first electronic component 125 may include a central processing unit (CPU) and a high-bandwidth memory (HBM). The CPU and the HBM are mounted on the first interposer 122 using respective solder bumps. Specifically, the CPU may overlap with a first portion of the first interposer 122, and the HBM may overlap with a second portion of the first interposer 122. Thus, the CPU and the HBM can be electrically connected with each other via the contact pads and the first wiring patterns of the first interposer 122. Moreover, some terminals of the CPU and/or the HBM may be electrically connected with the contact pads formed on the upper substrate surface 110a via conductive bumps.

Further, the second interposer 130 is disposed above the at least one first electronic component 125. The second interposer 130 may be also made of semiconductor material, glass, or organic materials with redistribution layers or wiring patterns formed therein. Specifically, in the example shown in FIG. 1, a plurality of redistribution layers 135 are formed in the second interposer 130, and can provide contact pads along its upper and lower surfaces. The first electronic component 125 is accommodated in the concave portion 130a of the second interposer 130, so as to reduce the overall size of the semiconductor package 100. A plurality of conductive bumps such as solder bumps, a copper pillars, or e-bar conductive structures may be formed on the contact pads at the protruding portion 130b of the second interposer 130. Then, the second interposer 130 may be mounted on the upper substrate surface 110a via the plurality of conductive bumps, and can be electrically connected with contact pads formed on the upper substrate surface 110a.

In some embodiments, as shown in FIG. 1, a first encapsulant 120 is formed between the upper substrate surface 110a and the second interposer 130 to encapsulate the first interposer 122 and the at least one first electronic component 125. The first encapsulant 120 can be made from, for example, an epoxy molding compound (EMC), or polymide compound, and can provide mechanical protection, environmental protection, and a hermetic seal for electronic components and structures in the semiconductor package 100.

Further, the at least one second electronic component 145 is mounted on the second interposer 130 and is electronically connected with the second interposer 130. The at least one second electronic component 145 may also include any of a variety of types of semiconductor dice, semiconductor packages, or discrete devices. For example, the at least one second electronic component 145 may include a graphics processing unit (GPU) and a high-bandwidth memory (HBM). Similarly, the at least one second electronic component 145 may also be small IC chips that contain different well-defined subsets of functionalities. The at least one second electronic component 145 can be mounted on the second interposer 130 by flip-chip bonding or any other suitable surface mounting techniques.

In some embodiments, as shown in FIG. 1, a second encapsulant 140 is formed on the second interposer 130 to encapsulate the at least one second electronic component 145. The second encapsulant 140 may be made of a same material as the first encapsulant 120. However, the present application is not limited thereto.

Continuing referring to FIG. 1, a first heat spreading sheet 150 is formed on the second encapsulant 140, a first heat-transfer passage 142 extends through the second encapsulant 140 and the second interposer 130, and between the first heat spreading sheet 150 and the at least one first electronic component 125; and a second heat-transfer passage 144 extends through a part of the second encapsulant 140, and between the first heat spreading sheet 150 and the at least one second electronic component 145.

The first heat spreading sheet 150 may include a material, whose thermal conductivity is at least higher than that of the second encapsulant 140. For example, the first heat spreading sheet 150 may include a conductive material such as aluminum (Al), tin (Sn), copper (Cu), silver (Ag), aluminum oxide (Al₂O₃), zinc oxide (ZnO), silicon carbide (SIC), aluminum nitride (AlN), boron nitride (BN), diamond, or any combination thereof. In some embodiments, the first heat-transfer passage 142 and/or the second heat-transfer passage 144 may include a thermal conductive layer. The thermal conductive layer may include a thermal conductive material as the first heat spreading sheet 150, or include a thermal interface material (TIM), a thermal conductive paste, a thermal conductive ink, or a thermal conductive epoxy, which is not elaborated herein.

It can be understood that, when heat is generated from the first electronic component 125 and the second electronic component 145, the heat may be easily transferred to the first heat spreading sheet 150 through the first heat-transfer passage 142 and the second heat-transfer passage 144. Accordingly, the semiconductor package 100 can have an improved heat dissipation capacity.

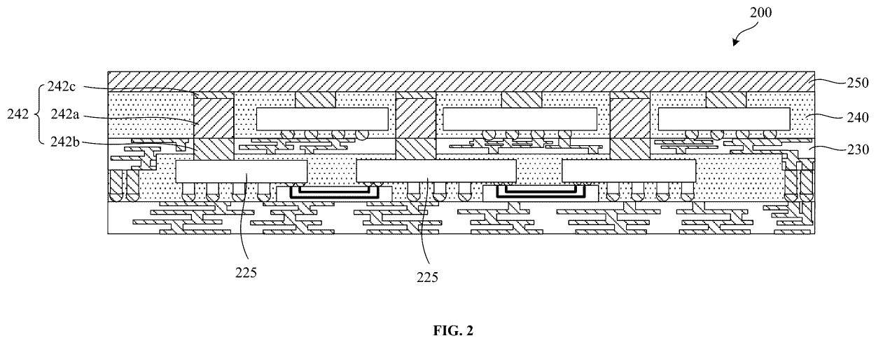

Referring now to FIG. 2, a semiconductor package 200 is illustrated according to another embodiment of the present application. The semiconductor package 200 may have similar structures and configurations as the semiconductor package 100 shown in FIG. 1. The similar or same parts between the semiconductor package 200 and the semiconductor package 100 will not be repeated herein.

The semiconductor package 200 of FIG. 2 is different from the semiconductor package 100 of FIG. 1 in that the semiconductor package 200 of FIG. 2 include stacked first heat-transfer passages.

Specifically, as shown in FIG. 2, a first heat-transfer passage 242 extends through the second encapsulant 240 and the second interposer 230, and between the first heat spreading sheet 250 and the at least one first electronic component 225. The first heat-transfer passage 242 may include a metal pillar 242a, a lower thermal conductive layer 242b disposed between a lower end of the metal pillar 242a and the at least one first electronic component 225, and an upper thermal conductive layer 242c disposed between an upper end of the metal pillar 242a and the first heat spreading sheet 250. The metal pillar 242a may include Al, Cu, Ag, or other metal material with a suitable thermal conductivity. The lower thermal conductive layer 242b and/or the upper thermal conductive layer 242c may include a thermal interface material, a thermal conductive paste, a thermal conductive ink, or a thermal conductive epoxy.

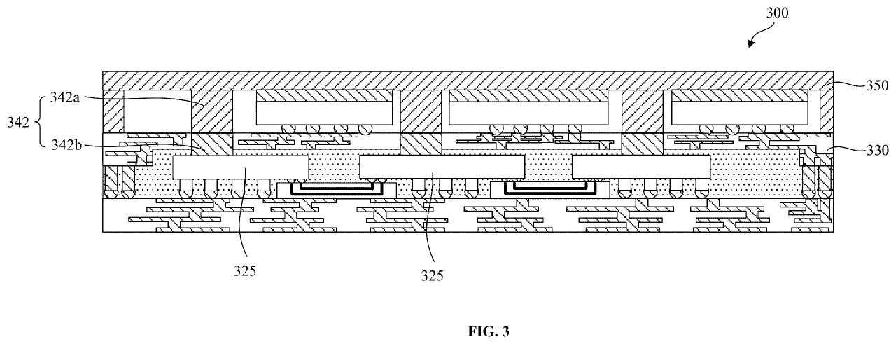

Referring now to FIG. 3, a semiconductor package 300 is illustrated according to another embodiment of the present application. The semiconductor package 300 may have similar structures and configurations as the semiconductor package 100 shown in FIG. 1. The similar or same parts between the semiconductor package 300 and the semiconductor package 100 will not be repeated herein.

The semiconductor package 300 of FIG. 3 is different from the semiconductor package 100 of FIG. 1 in that the semiconductor package 300 of FIG. 3 does not include the second encapsulant, but include stacked first heat-transfer passages.

Specifically, as shown in FIG. 3, a first heat-transfer passage 342 extends through the second interposer 330, and between the first heat spreading sheet 350 and the at least one first electronic component 325. The first heat-transfer passage 342 may include a metal column 342a, and a thermal conductive layer 342b disposed between a lower end of the metal column 342a and the at least one first electronic component 325. The metal column 342a may include Al, Cu, Ag, or other metal material with a suitable thermal conductivity. The thermal conductive layer 342b may include a thermal interface material, a thermal conductive paste, a thermal conductive ink, or a thermal conductive epoxy.

In some embodiments, the metal column 342a and the first heat spreading sheet 350 are formed as a whole. In other embodiments, the metal column 342a may be directly attached to the first heat spreading sheet 350 by any suitable attachment means such as welding or adhesive. In other words, the metal column 342a and the first heat spreading sheet 350 may be different parts of a metal frame, and the metal frame can be directly attached to the second interposer 330 and the thermal conductive layer 342b via the vertically extending columns shown in FIG. 3, without the second encapsulant 140 or 240 of shown in FIG. 1 or FIG. 2.

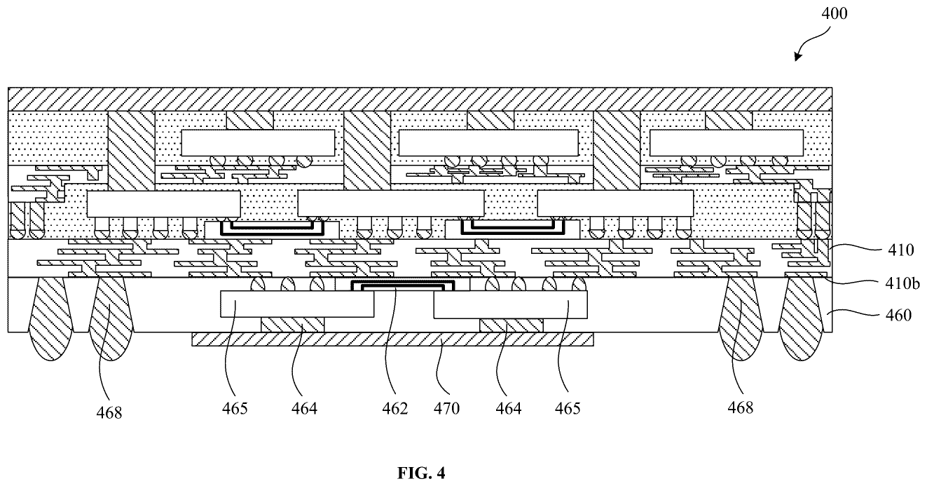

Referring now to FIG. 4, a semiconductor package 400 is illustrated according to another embodiment of the present application. The semiconductor package 400 may have similar structures and configurations as the semiconductor package 100 shown in FIG. 1. The similar or same parts between the semiconductor package 400 and the semiconductor package 100 will not be repeated herein.

The semiconductor package 400 of FIG. 4 is different from the semiconductor package 100 of FIG. 1 in that the semiconductor package 400 of FIG. 4 is formed using a Double Side Molding (DSM) technology.

Specifically, as shown in FIG. 4, the semiconductor package 400 further includes a third interposer 462, and the third interposer 462 is attached on the lower substrate surface 410b of the substrate 410. The third interposer 462 may have similar structures and configurations as the first interposer 122 shown in FIG. 1, and will not be elaborated herein. At least one third electronic component 465 is mounted on the third interposer 462, and is electronically connected with the third interposer 462. A third encapsulant 460 is formed on the lower substrate surface 410b of the substrate 410 to encapsulate the at least one third electronic component 465. A second heat spreading sheet 470 is formed on the third encapsulant 460, and a third heat-transfer passage 464 is formed in the third encapsulant 460 and extends between the second heat spreading sheet 470 and the at least one third electronic component 465. The third heat-transfer passage 464 may include a metal material, a thermal interface material, a thermal conductive paste, a thermal conductive ink, a thermal conductive epoxy, etc.

Further, the third encapsulant 460 has a plurality of cavities exposing a plurality of contact pads formed on the lower substrate surface 410b, and a plurality of conductive bumps 468 are formed in the plurality of cavities, respectively. In the example shown in FIG. 4, the conductive bumps 468 are illustrated as solder bumps, but the present application is not limited thereto. In some other embodiments, the conductive bumps 468 may include conductive pillars, or copper balls. In a case where the semiconductor package 400 is mounted on an external device or substrate, such as a printed circuit board (PCB), the conductive bumps 468 may be used for electrically connecting the semiconductor package 400 to the external device or substrate.

According to another aspect of the present application, a method for forming a semiconductor package is provided. The method may be used to make any of the semiconductor packages shown in FIGS. 1-4, for example.

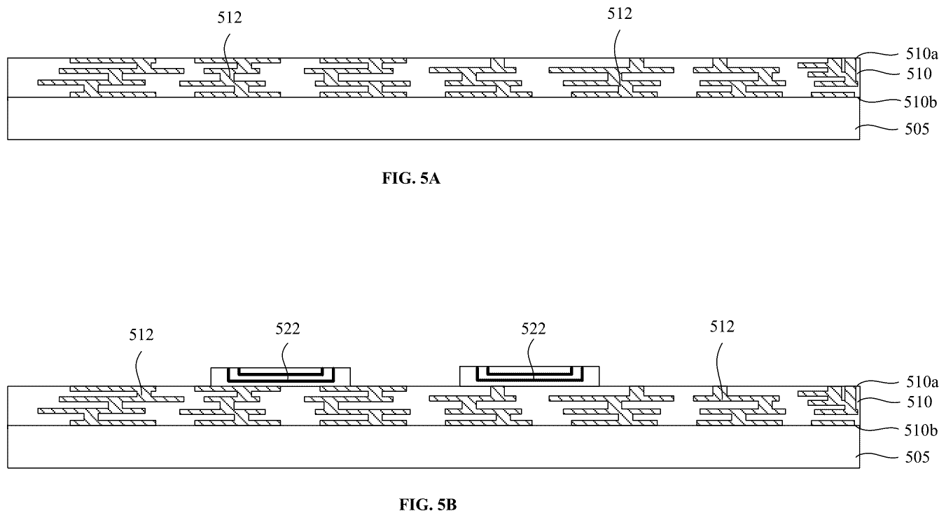

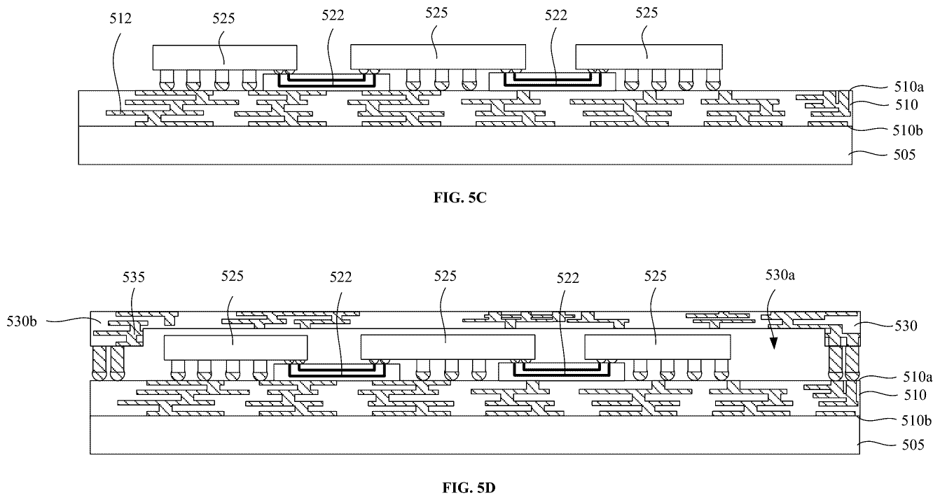

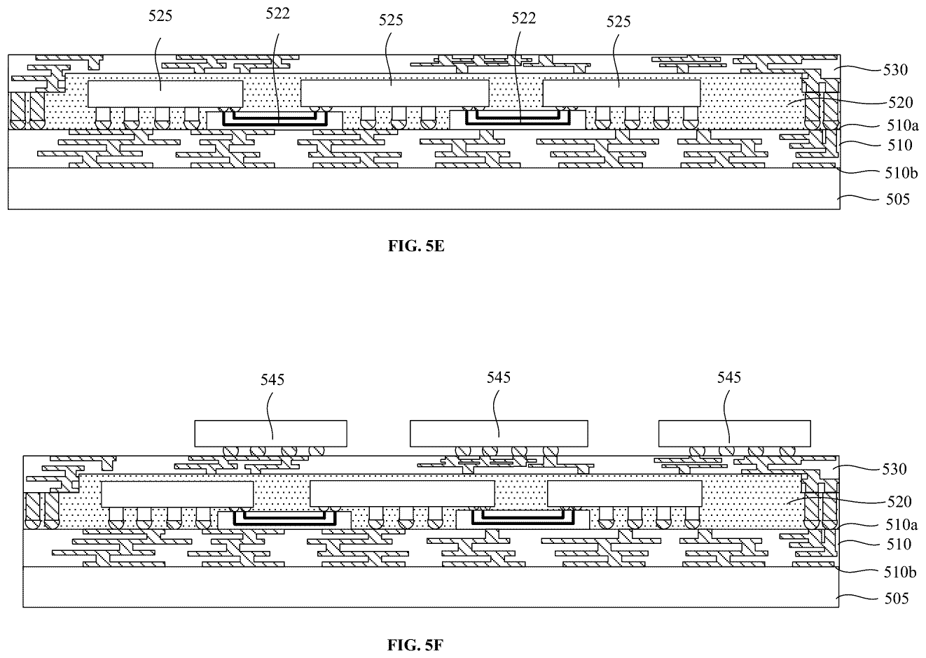

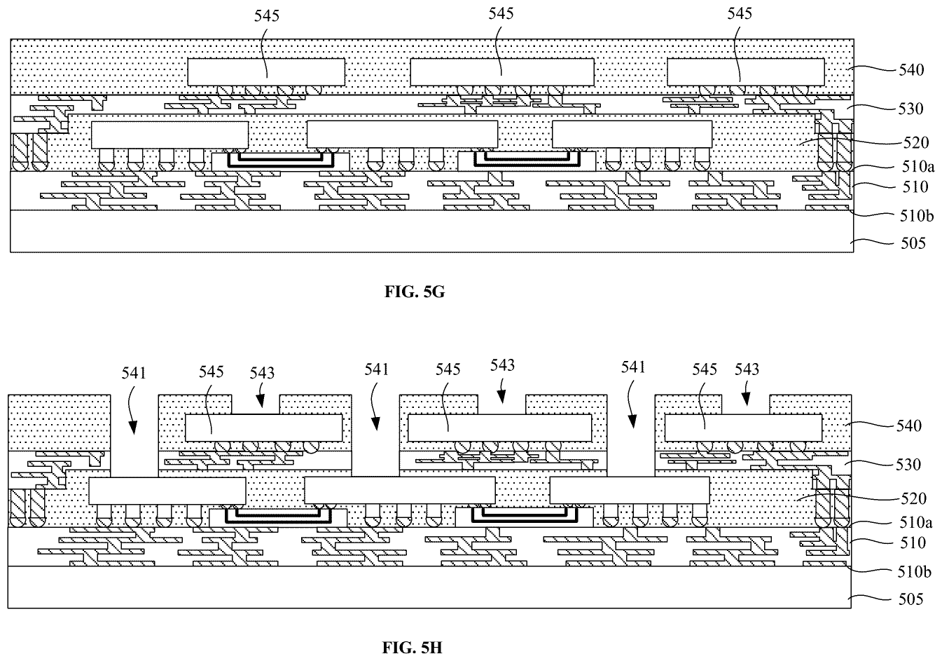

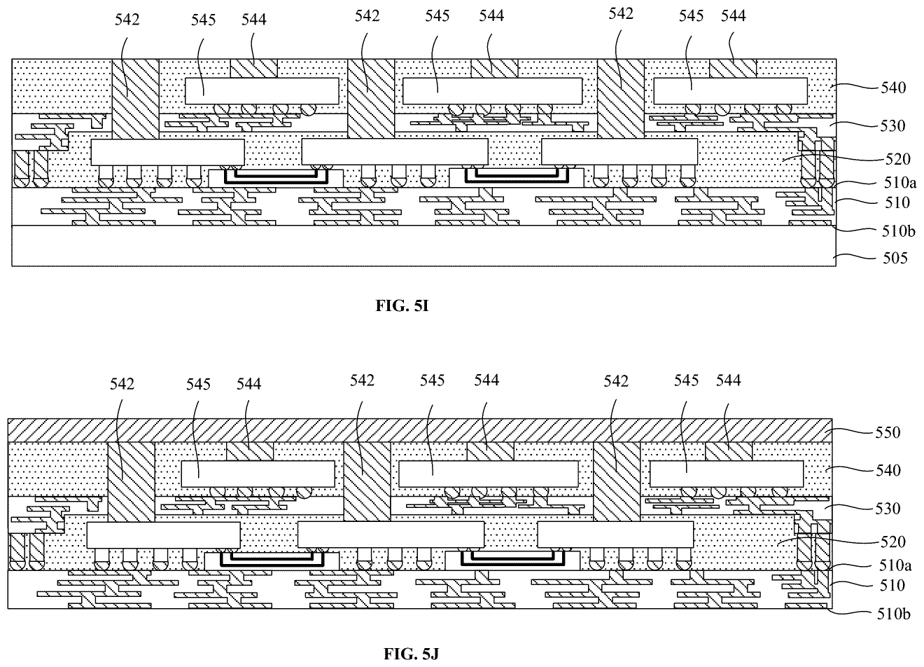

Referring to FIGS. 5A-5J, cross-sectional views illustrating a method for making a semiconductor package are shown according to an embodiment of the present application. For example, the method may be used to make the semiconductor package 100 shown in FIG. 1.

As shown in FIG. 5A, a substrate 510 is provided. The substrate 510 has an upper surface 510a and a lower surface 510b. The substrate 510 is attached on a carrier 505.

Specifically, the substrate 510 can provide support and connectivity for electronic components and devices. In some embodiments, the substrate 510 may include a plurality of interconnection structures. The interconnection structures can provide connectivity for electronic components mounted on the substrate 510. The interconnection structures may define pads, traces and plugs through which electrical signals or voltages can be distributed horizontally and vertically across the substrate 510. For example, as shown in FIG. 5A, the interconnection structures may include a plurality of redistribution structures 512, and the redistribution structures 512 can provide contact pads along the upper surface 510a and the lower surface 510b.

The carrier 505 may be a flat sheet of organic material, glass, silicon, polymer, or any other material suitable to provide physical support of the substrate 510 during the manufacturing process. An optional double-sided tape, thermal release layer, UV release layer, or other appropriate interface layer can be disposed between carrier 505 and the substrate 510.

Referring to FIG. 5B, at least one first interposer 522 is attached on the upper substrate surface 510a.

In some embodiments, an adhesive may be used to attach the at least one first interposer 522 on the upper substrate surface 510a. For example, the adhesive is first attached to the upper substrate surface 510a, and then the first interposer 522 is attached on the upper substrate surface 510a by the adhesive. The adhesive may include a non-conductive film, an anisotropic conductive film, an ultraviolet (UV) film, an instant adhesive, a thermosetting adhesive, or any other suitable adhesive materials.

The first interposer 522 may be made of semiconductor material, glass, or organic materials with redistribution layers or wiring patterns formed therein. Preferably, the first interposer 522 is a silicon-based interposer. The first interposer 522 can support fine pitches for TSVs and traces used in signal and power distribution, and may have a thermal expansion coefficient which can match that of the semiconductor die or chiplet it is in contact with. For example, the first interposer 522 may include a semiconductor layer, a plurality of wiring patterns formed on the semiconductor layer, and a plurality of contact pads connected with the wiring patterns. The wiring patterns may include TSVs and traces with fine pitches. The contact pads can provide connectivity for electrical components mounted thereon.

Referring to FIG. 5C, at least one first electronic component 525 is mounted on the first interposer 522, and the at least one first electronic component 525 is electronically connected with the first interposer 522.

The first electronic component 525 can be mounted on the first interposer 522 by flip-chip bonding or other suitable surface mounting techniques. For example, solder paste may be deposited or printed onto contact pads where the first electronic component 525 may be surface mounted. Then, the first electronic component 525 may be placed on the upper surface of first interposer 522 with terminals of the first electronic component 525 in contact with and over the solder paste. The solder paste may be reflowed to mechanically and electrically couple the first electronic component 525 to the contact pads on the upper surface of the first interposer 522.

The first electronic component 525 may include any of a variety of types of semiconductor dice, semiconductor packages, or discrete devices. For example, the at least one first electronic component 525 may include a central processing unit (CPU) and a high-bandwidth memory (HBM). The CPU and the HBM are mounted on the first interposer 522 using respective solder bumps. In some embodiments, as shown in FIG. 5C, some terminals of the first electronic component 525 may be electrically connected with the contact pads formed on the upper substrate surface 510a via conductive bumps.

Referring to FIG. 5D, a second interposer 530 is mounted above the at least one first electronic component 525. The second interposer 530 may have a concave portion 530a and a protruding portion 530b. The at least one first electronic component 525 is accommodated in the concave portion 530a, and the protruding portion 530b is mounted on the upper substrate surface 510a.

In some embodiments, a plurality of conductive bumps such as solder bumps, a copper pillars, or e-bar conductive structures may be formed on contact pads at the protruding portion 530b of the second interposer 530. Then, the second interposer 530 can be mounted on the upper substrate surface 510a via the plurality of conductive bumps.

The second interposer 530 may be made of semiconductor material, glass, or organic materials with redistribution layers or wiring patterns formed therein. For example, as shown in FIG. 5D, a plurality of redistribution layers 535 are formed in the second interposer 530 to provide contact pads along its upper and lower surfaces.

Referring to FIG. 5E, a first encapsulant 520 is formed between the upper substrate surface 510a and the second interposer 530 to encapsulate the first interposer 522 and the at least one first electronic component 525.

In some embodiments, the first encapsulant 520 may be formed using a molding process such as a compression molding process or an injection molding process. In some other embodiments, the first encapsulant 520 may be formed using paste printing, transfer molding, liquid encapsulant molding, vacuum lamination, or other suitable process. The first encapsulant 520 may be made of polymer composite material, such as epoxy resin with filler, epoxy acrylate with filler, or polymer with proper filler, but the scope of this application is not limited thereto.

Referring to FIG. 5F, at least one second electronic component 545 is mounted on the second interposer 530, and the at least one second electronic component 545 is electronically connected with the second interposer 530.

The second electronic component 545 may be mounted on the second interposer 530 by flip-chip bonding or other suitable surface mounting techniques. The at least one second electronic component 545 may also include any of a variety of types of semiconductor dice, semiconductor packages, or discrete devices. For example, the at least one second electronic component 545 may include a graphics processing unit (GPU) and a high-bandwidth memory (HBM).

Referring to FIG. 5G, a second encapsulant 540 is formed on the second interposer 530 to encapsulate the at least one second electronic component 545.

In some embodiments, the second encapsulant 540 may be formed using a molding process such as a compression molding process or an injection molding process. In some other embodiments, the second encapsulant 540 may be formed using paste printing, transfer molding, liquid encapsulant molding, vacuum lamination, spin coating, or other suitable process. The second encapsulant 540 may be made of polymer composite material, such as epoxy resin with filler, epoxy acrylate with filler, or polymer with proper filler, but the scope of this application is not limited thereto. In some examples, the second encapsulant 540 may be planarized, if desired.

Referring to FIG. 5H, a first trench 541 is formed to expose an upper surface of the at least one first electronic component 525, and a second trench 543 is formed in the second encapsulant 540 to expose an upper surface of the at least one second electronic component 545.

The first trench 541 extends through the second encapsulant 540 and the second interposer 530. In some cases, if a portion of the first encapsulant 520 is formed between the upper surface of the first electronic component 525 and the second interposer 530, the first trench 541 also extends through this portion of the first encapsulant 520.

In some embodiments, a laser ablation process may be employed to form the first trench 541 and/or the second trench 543. The laser ablation technique can accurately control a shape and/or a depth of the first trench 541 and/or the second trench 543. However, the present application is not limited thereto. In other embodiments, the first trench 541 and/or the second trench 543 may be formed by a saw blade, a dry or wet etching process, or any other process known in the art so long as the encapsulant and/or interposer material can be removed as desired. In some other embodiments, after forming the trenches, a cleaning process for removing residuals of the encapsulant material at the trenches may further be performed.

Referring to both FIG. 5H and FIG. 5I, a first heat-transfer passage 542 is formed in the first trench 541, and a second heat-transfer passage 544 is formed in the second trench 543.

In some embodiments, the first heat-transfer passage 542 and/or the second heat-transfer passage 544 may include a thermal conductive layer. The thermal conductive layer may include a thermal conductive material, such as a metal material, a thermal interface material (TIM), a thermal conductive paste, a thermal conductive ink, a thermal conductive epoxy, etc.

In some embodiments, the first heat-transfer passage 542 and/or the second heat-transfer passage 544 may be formed by plating, spray coating, sputtering, or any other suitable deposition process. In some embodiments, the first heat-transfer passage 542 and/or the second heat-transfer passage 544 may be planarized, if desired.

As last, referring to FIG. 5J, a first heat spreading sheet 550 is formed on the second encapsulant 540. The first heat spreading sheet 550 is in contact with the first heat-transfer passage 542 and the second heat-transfer passage 544.

In some embodiments, the first heat spreading sheet 550 may be attached on the second encapsulant 540. In some other embodiments, the first heat spreading sheet 550 may be formed on the second encapsulant 540 by plating, spray coating, sputtering, or any other suitable deposition process. The first heat spreading sheet 550 may include a material, whose thermal conductivity is at least higher than that of the second encapsulant 540. After the first heat spreading sheet 550 is formed on the second encapsulant 540, the carrier 505 is also removed from the substrate 510.

In addition, although it is only illustrated a single unit of semiconductor package in the steps of FIGS. 5A to 5J, a strip type of semiconductor packages, i.e., various semiconductor packages formed in a substrate strip, can be made using the processes shown in FIGS. 5A to 5J. For example, a singulation step may be performed to the strip after the step for forming the first heat spreading sheet 550 as shown in FIG. 5J.

While the method for making the semiconductor package of the present application is described in conjunction with corresponding FIGS. 5A to 5J, it will be understood by those skilled in the art that modifications and adaptations to the method may be made without departing from the scope of the present invention.

In some other embodiments, after the first trench 541 is formed as shown in FIG. 5H, a different first heat-transfer passage may be formed in the first trench 541. The first heat-transfer passage may include a metal pillar, a lower thermal conductive layer disposed between a lower end of the metal pillar and the at least one first electronic component, and an upper thermal conductive layer disposed between an upper end of the metal pillar and the first heat spreading sheet. Accordingly, the method described above can be used to make the semiconductor package 200 shown in FIG. 2.

In some other embodiments, after the second electronic component 545 is mounted on the second interposer 530 as shown in FIG. 5F, a first trench is formed to extend through the second interposer and expose an upper surface of the at least one first electronic component. Then, a first thermal conductive layer is formed in the first trench, and a second thermal conductive layer is formed on the at least one second electronic component. At last, a metal frame is mounted on the second interposer. The metal frame includes a metal column attached with the first thermal conductive layer, and a metal plate attached with the second thermal conductive layer. The metal plate may serve as the first heat spreading sheet, metal column may serve as the first heat-transfer passage. Accordingly, the semiconductor package 300 shown in FIG. 3 can be formed.

In some other embodiments, after the first heat spreading sheet 550 is formed on the second encapsulant 540 as shown in FIG. 5J, a third interposer is attached on the lower substrate surface, and at least one third electronic component is mounted on the third interposer. The at least one third electronic component may be electronically connected with the third interposer. Afterwards, a third encapsulant is formed on the lower substrate surface to encapsulate the at least one third electronic component, and a third trench is formed in the third encapsulant to expose a surface of the at least one third electronic component. Afterwards, a third heat-transfer passage is formed in the third trench, and a second heat spreading sheet is formed on the third encapsulant. The second heat spreading sheet is in contact with the third heat-transfer passage. Moreover, a plurality of cavities is formed in the third encapsulant to expose a plurality of contact pads formed on the lower substrate surface, and a plurality of conductive bumps is formed in the plurality of cavities, respectively. Accordingly, the semiconductor package 400 shown in FIG. 4 can be formed.

The discussion herein included numerous illustrative figures that showed various portions of a semiconductor package and a method for making the same. For illustrative clarity, such figures did not show all aspects of each example package. Any of the example packages and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a substrate having a lower substrate surface and an upper substrate surface;
a first interposer attached on the upper substrate surface;
at least one first electronic component mounted on and electronically connected with the first interposer;
a second interposer disposed above the at least one first electronic component, wherein the second interposer has a concave portion and a protruding portion, the at least one first electronic component is accommodated in the concave portion, and the protruding portion is mounted on the upper substrate surface; and
at least one second electronic component mounted on and electronically connected with the second interposer.

2. The semiconductor package of claim 1, further comprising:
a first encapsulant disposed on the upper substrate surface and encapsulating the first interposer and the at least one first electronic component.

3. The semiconductor package of claim 1, further comprising:
a second encapsulant disposed on the second interposer and encapsulating the at least one second electronic component.

4. The semiconductor package of claim 1, further comprising:
a first heat spreading sheet disposed above the at least one second electronic component;
a first heat-transfer passage extending between the first heat spreading sheet and the at least one first electronic component; and
a second heat-transfer passage extending between the first heat spreading sheet and the at least one second electronic component.

5. The semiconductor package of claim 4, wherein the first heat-transfer passage or the second heat-transfer passage comprises a thermal conductive layer, and the thermal conductive layer comprises a thermal interface material, a thermal conductive paste, a thermal conductive ink, or a thermal conductive epoxy.

6. The semiconductor package of claim 4, wherein the first heat-transfer passage comprises a metal pillar, a lower thermal conductive layer disposed between a lower end of the metal pillar and the at least one first electronic component, and an upper thermal conductive layer disposed between an upper end of the metal pillar and the first heat spreading sheet.

7. The semiconductor package of claim 4, wherein the first heat-transfer passage comprises a metal column, and a thermal conductive layer disposed between a lower end of the metal column and the at least one first electronic component, and
wherein the metal column and the first heat spreading sheet are formed as a whole, or the metal column is directly attached to the first heat spreading sheet.

8. The semiconductor package of claim 1, further comprising:
a third interposer disposed on the lower substrate surface;
at least one third electronic component mounted on and electronically connected with the third interposer;
a second heat spreading sheet disposed below the at least one third electronic component; and
a third heat-transfer passage extending between the second heat spreading sheet and the at least one third electronic component.

9. The semiconductor package of claim 8, further comprising:
a third encapsulant disposed on the lower substrate surface and encapsulating the at least one third electronic component, wherein the third encapsulant has a plurality of cavities exposing a plurality of contact pads formed on the lower substrate surface respectively; and
a plurality of conductive bumps formed in the plurality of cavities, respectively.

10. A method for forming a semiconductor package, comprising:
providing a substrate having a lower substrate surface and an upper substrate surface;
attaching a first interposer on the upper substrate surface;
mounting at least one first electronic component on the first interposer, the at least one first electronic component being electronically connected with the first interposer;
mounting a second interposer above the at least one first electronic component, wherein the second interposer has a concave portion and a protruding portion, the at least one first electronic component is accommodated in the concave portion, and the protruding portion is mounted on the upper substrate surface; and
mounting at least one second electronic component on the second interposer, the at least one second electronic component being electronically connected with the second interposer.

11. The method of claim 10, wherein after mounting the second interposer above the at least one first electronic component, the method further comprises:
forming a first encapsulant between the upper substrate surface and the second interposer to encapsulate the first interposer and the at least one first electronic component.

12. The method of claim 11, wherein after mounting the at least one second electronic component on the second interposer, the method further comprises:
forming a second encapsulant on the second interposer to encapsulate the at least one second electronic component.

13. The method of claim 12, further comprising:
forming a first trench extending through the second encapsulant and the second interposer to expose an upper surface of the at least one first electronic component;
forming a second trench in the second encapsulant to expose an upper surface of the at least one second electronic component;
forming a first heat-transfer passage in the first trench;
forming a second heat-transfer passage in the second trench; and
forming a first heat spreading sheet on the second encapsulant, the first heat spreading sheet being in contact with the first heat-transfer passage and the second heat-transfer passage.

14. The method of claim 13, wherein the first heat-transfer passage or the second heat-transfer passage comprises a thermal conductive layer, and the thermal conductive layer comprises a thermal interface material, a conductive paste, a thermal conductive ink, or a thermal conductive epoxy.

15. The method of claim 13, wherein the first heat-transfer passage comprises a metal pillar, a lower thermal conductive layer disposed between a lower end of the metal pillar and the at least one first electronic component, and an upper thermal conductive layer disposed between an upper end of the metal pillar and the first heat spreading sheet.

16. The method of claim 11, further comprising:
forming a first trench extending through the second interposer to expose an upper surface of the at least one first electronic component;
forming a first thermal conductive layer in the first trench;
forming a second thermal conductive layer on the at least one second electronic component; and
mounting a metal frame on the second interposer, wherein the metal frame comprises a metal column attached with the first thermal conductive layer, and a metal plate attached with the second thermal conductive layer.

17. The method of claim 11, further comprising:
attaching a third interposer on the lower substrate surface;
mounting at least one third electronic component on the third interposer, the at least one third electronic component being electronically connected with the third interposer;
forming a third encapsulant on the lower substrate surface to encapsulate the at least one third electronic component;
forming a third trench in the third encapsulant to expose a surface of the at least one third electronic component;
forming a third heat-transfer passage in the third trench; and
forming a second heat spreading sheet on the third encapsulant, the second heat spreading sheet being in contact with the third heat-transfer passage.

18. The method of claim 17, further comprising:
forming a plurality of cavities in the third encapsulant to expose a plurality of contact pads formed on the lower substrate surface; and
forming a plurality of conductive bumps in the plurality of cavities, respectively.
